(19) United States
(12) Patent Application Publication
(10) Pub. No.: US 2025/0372526 A1
(43) Pub. Date: Dec. 4, 2025

(54) INTERPOSER DEVICES WITH MUTLIPLE INTERPOSER CORES

(71) Applicant: Applied Materials, Inc., Santa Clara, CA (US)

(72) Inventors: Subramani Kengeri, Santa Clara, CA (US); Tameesh Suri, San Jose, CA (US); Meghna Maheshkumar Patel, Navsari (IN); Khyat Kamal Patel, Bilimora (IN)

(21) Appl. No.: 19/219,146

(22) Filed: May 27, 2025

Related U.S. Application Data
(60) Provisional application No. 63/671,929, filed on Jul. 16, 2024.

(30) Foreign Application Priority Data
May 31, 2024 (IN) 202441042341

(51) Int. Cl. H01L 23/538; H01L 21/48; H01L 23/00; H01L 23/14; H01L 25/065

(52) U.S. Cl. CPC H01L 23/5385; H01L 21/4853; H01L 21/4857; H01L 21/486; H01L 23/145; H01L 23/5381; H01L 24/16; H01L 25/0655; H01L 2224/16227; H01L 2924/1511

(57) ABSTRACT

Embodiments described herein relate interposer devices with multiple interposer cores. For example, a system can include a first stack of an interposer device and a second stack of the interposer device. The first stack can include a first core including a first core substrate and the second stack can include a second core including a second core substrate.

### CROSS-REFERENCE TO RELATED APPLICATION(S)

The present application claims priority to Indian patent application Ser. No. 202441042341 filed on May 31, 2024, and U.S. Provisional Patent Application No. 63/671,929, filed on Jul. 16, 2024, the entire contents of each of which are hereby incorporated by reference herein.

### TECHNICAL FIELD

The instant specification generally relates to packaging for electronic devices, such as optical devices. More specifically, the instant specification relates to interposer devices with multiple interposer cores (“cores”).

### BACKGROUND

With recent advancements, packaging options for electronic devices have expanded to include a wide range of choices. These options span from the conventional flip-chips to more advanced packaging technologies, such as 2.5 dimensional (2.5D) and three-dimensional (3D) integration, that incorporate multiple components (e.g., chiplets) in a modular manner. Apart from the market demand for compact devices with enhanced functionality, the concept of heterogeneous integration is also fueling this trend. In this approach of packaging, designers bring together the multiple components, which may come from different suppliers, and integrate them into a single package on a substrate with interconnect structures (e.g., conductive lines and vias).

### SUMMARY

In some embodiments, a system is provided. The system includes a first stack of an interposer device and a second stack of the interposer device. The first stack includes a first core including a first core substrate and the second stack includes a second core including a second core substrate.

In some embodiments, a method is provided. The method includes forming a first stack of a plurality of stacks of an interposer device, forming a second stack of the plurality of stacks, and forming the interposer device by combining each stack of the plurality of stacks. The first stack includes a first core including a first core substrate and the second stack includes a second core including a second core substrate.

### BRIEF DESCRIPTION OF THE DRAWINGS

Aspects and implementations of the present disclosure will be understood more fully from the detailed description given below and from the accompanying drawings, which are intended to illustrate aspects and implementations by way of example and not limitation.

FIG. 1 is a block diagram illustrating a system including an interposer device with multiple interposer cores, in accordance with some embodiments.

FIGS. 2A-2H are block diagrams illustrating an example process of forming a system or device including an interposer device with multiple interposer cores, in accordance with some embodiments.

FIG. 3 is a block diagram of an example method of forming a system or device including an interposer device with multiple interposer cores, in accordance with some embodiments.

### DETAILED DESCRIPTION

Interposers are components that can be used to enable the implementation of advanced packaging including multiple dies (e.g., integrated circuits (ICs) or chips) and/or chiplets. Interposers can serve as a foundation for placing individual dies and feature tiny interconnects for attaching to the main packaging substrate. For example, a device can include an interposer having a first side located on a set of balls (e.g., ball grid array (BGA)) formed on a printed circuit board (PCB). A set of dies can be formed on a second of the interposer opposite the first side. Each pad can be being electrically connected to the interposer by a respective set of balls (e.g., BGA)).

An interposer device can include a stack of layers including a first redistribution layer (RDL) formed on the set of balls formed on the PCB, a core formed on the first RDL, a second RDL formed on the core, and an interposer (e.g., organic interposer) disposed on the second RDL. An RDL is an additional conductive layer integrated into the packaging of a device that serves to reroute and/or optimize input/output (I/O) connections. For example, RDLs can be used to interconnect multiple dies and/or chiplets in advanced packaging technologies (e.g., 2.5D and 3D packaging).

More specifically, the set of dies can be formed on the interposer. A respective set of interconnect structures (e.g., conductive lines and vias) can be formed within an RDL substrate of each RDL and an interposer substrate of the interposer, and a set of through substrate vias (TSVs) can be formed within a core substrate of the core. The set of interconnect structures of the interposer can further include a set of bridges, where each bridge of the set of bridges connects a respective pair of dies of the set of dies. In some implementations, the set of bridges includes a set of embedded multi-die interconnect bridges (EMIBs).

For example, the set of interconnect structures of the first RDL can be in contact with the set of balls formed on the PCB to establish an electrical connection with the PCB. The set of TSVs can be connected to the set of interconnect structures of the first RDL and the set of interconnect structures of the second RDL to establish an electrical connection between the first RDL and the second RDL. The set of interconnect structures of the second RDL can be connected to the set of interconnect structures of the interposer to establish an electrical connection between the second RDL and the interposer. The set of interconnect structures of the interposer can be connected to the sets of balls formed on the second RDL to establish an electrical connection between the second RDL and the sets of balls formed on the second RDL. Accordingly, an interposer can function as a substrate for multiple dies.

A substrate (e.g., a core substrate or an interposer substrate) can be formed from any suitable material materials. The choice of material used to form a substrate can depend on the specific requirements of the application and the trade-offs between cost, performance, and reliability. Examples of materials that can be used to form a substrate include glass, silicon (Si), organic material, laminate material, etc.

For example, glass can withstand harsh environment conditions. For example, glass has high resistance to moisture, excellent resistance to corrosion or degradation cause by chemical exposure, and can withstand high temperatures. Glass has high thermal stability due to a low coefficient of thermal expansion (e.g., better thermal stability than Si), making glass less prone to warping, deforming or cracking due to temperature changes, which reduces the risk of stress-induced failures. The high resistance to breakage and ability to withstand mechanical stress makes glass suitable for applications that would benefit from reliability. Glass can offer low signal loss and minimal interference, enabling excellent performance in high-speed electronic devices. Thus, the properties of glass can help ensure the long-term reliability and performance of electronic devices in harsh operating conditions. However, substrates formed from glass can have challenges with cracking and the drilling of TSVs, and may be less flexible compared to other options.

As another example, Si can offer good electrical performance and high thermal conductivity. As a substrate material, Si is commonly used in semiconductor manufacturing due to its compatibility with ICs, and excellent dimensional stability and ability to handle high temperatures due to its high thermal conductivity (which can allow for heat dissipation). For example, Si can improve mechanical stability and dimensional accuracy making it more reliable than other materials (e.g., organic material). The high thermal conductivity of Si can be particularly beneficial in applications where thermal management is crucial, such as high-power devices or those operating at high temperatures. Si can exhibit excellent electrical properties, including high carrier mobility and low resistivity. This enables efficient electrical signal transmission and low power consumption in electronic devices. Si can be highly compatible with semiconductor manufacturing processes and ICs and provide a reliable platform for the fabrication of complex electronic components and allow for precise integration of active devices. However, Si substrates can be much more expensive than other types of substrates (e.g., organic substrates), and can be susceptible to warpage and reliability concerns when thinned and at large sizes.

As yet another example, organic materials, such as epoxy, polyimide, etc., can be cost-effective and flexible. Organic materials are commonly used in consumer electronics due to their lighter weight and lower manufacturing costs. However, organic materials can have lower thermal conductivity and can be less stable in high-temperature environments than other types of materials. Organic materials can also be more susceptible to moisture absorption than other types of materials, which can affect their reliability over time.

One of the most used materials in consumer electronics are organic materials due their lighter weight and cost effectiveness. However, organic materials can be less stable in high temperature environments and can cause warpage and loose reliability over time when used as substrate materials for interposers. Reliability and warpage problems can be exacerbated as future advanced packaging substrates and interposers scale in size. Further increasing the size of an interposer without modifying the stack up can be more expensive if there are any defects detected after fabrication process as replacing a larger integrated stack with single core can be costly.

Furthermore, scaling of interposer and/or substrate size can include scaling of compute, memory and I/O resources on a package and can require additional metal layers and stack up. Accordingly, processing additional layers on the same substrate can lead to increased complexity, time and cost.

Embodiments of the present disclosure can address these and other drawbacks by providing for interposer devices with multiple cores. For example, an interposer device described herein can be referred to as a “hybrid interposer device.” An interposer device described herein can be used to build complex, large, advanced packages that are scalable for future compute platform requirements.

More specifically, an interposer device described herein can include at least two stacks. Each stack can include a core disposed between a first RDL including a first set of interconnect structures and a second RDL including a second set of interconnect structures. The core can include a set of TSVs formed within a core substrate, where the set of TSVs is connected to the first and second set of interconnect structures to provide an electrical connection between the first RDL and the second RDL. The first RDL of an initial stack (e.g., bottom RDL of the initial stack) can be formed on a set of balls (e.g., BGA) formed on a PCB. Multiple sets of balls (e.g., BGAs) can be formed on a second RDL of a final stack (e.g., top RDL of the final stack), where each die of a set of dies can be formed on a respective set of balls formed on the second RDL of the final stack. In some embodiments, an RDL layer of a first stack is hybrid bonded to an RDL layer of a second stack.

Each core substrate described herein can be formed from any suitable material. Examples of suitable materials include Si, glass, organic, laminate, etc. In some embodiments, at least one core substrate is formed from a different material than another core. In some embodiments, each core substrate is formed from the same material. In some embodiments, at least one core substrate is formed from a different material from the interposer substrate. In some embodiments, multiples core substrates are formed from a different material from the interposer substrate. Illustrative, a first core substrate can be formed from glass or Si, a second core substrate can be formed from glass or Si, and the interposer substrate can be formed from an organic material (“organic interposer”). Accordingly, by leveraging the different properties of various types of materials, embodiments described herein can enable the use hybrid stack-up of different substrate materials for use in advanced packaging structures to meet end platform performance needs.

The conductive lines and/or vias of a set of interconnects can individually be tailored to support required functionality. For example, high density interconnectivity may need a few layers of fine line/space (L/S), while serial chiplet and off-package interfaces (e.g., serializer/deserializer or SERDES) work fine with coarse L/S. Line refers to the width of a material formed on a substrate, and space refers to the gap between adjacent lines. Embodiments described herein can support various assembly options, such as hybrid bonding, microbumps, controller collapse chip connect (C4) bumps, etc., depending on the needs of the substrate connectivity and other device requirements.

Embodiments described herein can provide for numerous other technical advantages. For example, an interposer device design described herein can reduce the number of metallization levels of each RDL (e.g., levels of conductive lines) as compared to other interposer device designs. For example, if the interposer device includes two stacks, then each RDL of the two stacks can have half the number of metallization levels as compared to the number of metallization levels of an RDL of an interposer having a single stack. Illustratively, if each RDL of an interposer having a single stack includes 8 metallization levels, then each RDL of an interposer having two stacks can include 4 metallization levels. The interposer device design can be used to reduce time to market (TTM) time by breaking up the interposer fabrication process into multiple processes. For example, if an interposer includes 16 RDLs, these 16 RDLs can be broken into 2 separate processes of 8 RDLs each, which can reduce TTM. Additionally, multiple stacks of an interposer device can be fabricated in parallel and then integrated together, each with minimal/optimal processing of conductive layers and stack up required to support on-package compute and memory. This can enable an interposer device described herein to achieve reduced warpage and increased reliability as compared with typical large monolithic interposers. For example, any defects in an interposer device described herein be detected early on by fabricating smaller layers in parallel analyzing each individual stack before combining the stacks to form the interposer device. Analyzing individual stacks of an interposer device described herein before integration (e.g., bonding) into the interposer device can prevent the need to replace a single large stack after identifying a defect in the single large stack. Accordingly, embodiments described herein can reduce time of manufacture, complexity and/or cost of interposer device fabrication.

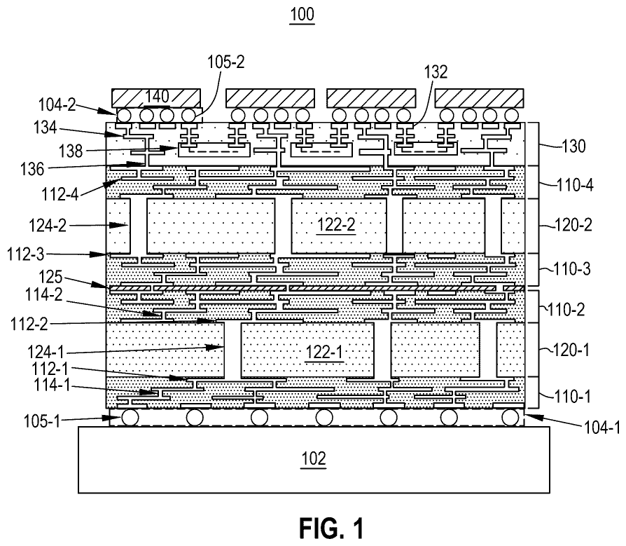

As another example, an interposer device described herein can utilize the benefits of organic materials such as cost effectiveness, flexibility and lower dielectric constants (leading to lower insertion loss than glass or Si and improved signal integrity) while addressing the issue of high temperature stability and reliability. Illustratively, the interposer substrate can be formed from an organic material, while each of the core substrates can include a same or different material (e.g., glass, silicon or laminate) depending on specific requirements of the application for an interposer device described herein. Further details regarding hybrid interposer devices are described below with reference to FIGS. 1-3.

FIG. 1 is a block diagram illustrating a system 100 (or device), in accordance with some embodiments. As shown in FIG. 1, the system 100 includes a PCB 102, and a set of balls (e.g., BGA) 104-1 including ball 105-1 formed on the PCB 102.

The system 100 can further include an interposer device formed on the set of balls 104-1. More specifically, the interposer device can be a hybrid interposer device. The interposer device can include a first stack including an RDL 110-1, an RDL 110-2 and a core 120-1 located between the RDLs 110-1 and 110-2. The interposer device can further include a second stack including an RDL 110-3, an RDL 110-4, and a core 120-2 located between the RDLs 110-3 and 110-4. The first stack is bonded to the second stack at an interface 125. For example, the interface 125 can include a solder resist. More specifically, the RDL 110-2 can be bonded to the RDL 110-3. In some embodiments, the first stack is bonded to the second stack using hybrid bonding.

As shown in FIG. 1, the RDL 110-1 can include a first set of interconnects including conductive lines (e.g., conductive line 112-1) and vias (e.g., via 114-1). For example, the first set of interconnects can include multiple conductive lines each in contact with a respective ball of the set of balls 104-1. The RDL 110-2 can include a second set of interconnects including conductive lines (e.g., conductive line 112-2) and vias (e.g., via 114-2). The core 120-1 can include a core substrate 122-1 and a first set of TSVs including TSV 124-1 formed within the core substrate 122-1. Each TSV of the first set of TSVs can be connected to a first pair of conductive lines, where a first conductive line of the first pair is adjacent to a boundary between the core 122-1 and the RDL 110-1, and a second conductive line of the first pair is adjacent to a boundary between the core 122-1 and the RDL 110-2.

As further shown in FIG. 1, the RDL 110-3 can include a third set of interconnects including conductive lines (e.g., conductive line 112-2) and vias (e.g., via 114-2). The RDL 110-4 can include a fourth set of interconnects including conductive lines (e.g., conductive line 112-4) and vias (e.g., via 114-2). The core 120-2 can include a core substrate 122-2 and a second set of TSVs including TSV 124-2 formed within the core substrate 122-2. Each TSV of the second set of TSVs can be connected to a second pair of conductive lines, where a first conductive line of the second pair is adjacent to a boundary between the core 122-2 and the RDL 110-3, and a second conductive line of the second pair is adjacent to a boundary between the core 122-2 and the RDL 110-4.

As further shown in FIG. 1, an interposer 130 can be formed on the RDL 110-4. In some embodiments, the interposer 130 is a layer of the second stack. In some embodiments, the interposer 130 is a layer formed on the second stack. The interposer 130 can include an interposer substrate 132, a fifth set of interconnects including conductive lines (e.g., conductive line 134) and vias (e.g., via 136).

Multiple sets of balls (e.g., BGAs) can be formed on the interposer 130. For example, a set of balls 104-2 including a ball 105-2 can be formed on the interposer 130. Each set of balls formed on the interposer 130 can be in contact with a respective die of a set of dies formed on the set of balls. For example, the set of balls 104-2 can be in contact with a die 140 formed on the set of balls 104-2. The fifth set of interconnects can further include a set of bridges (e.g., bridge 138). Each bridge of the set of bridges connects a respective pair of dies of the set of dies. In some embodiments, the bridge 138 is an EMIB.

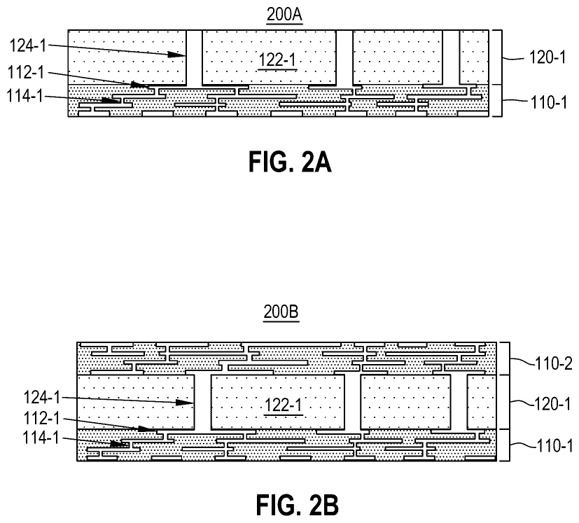

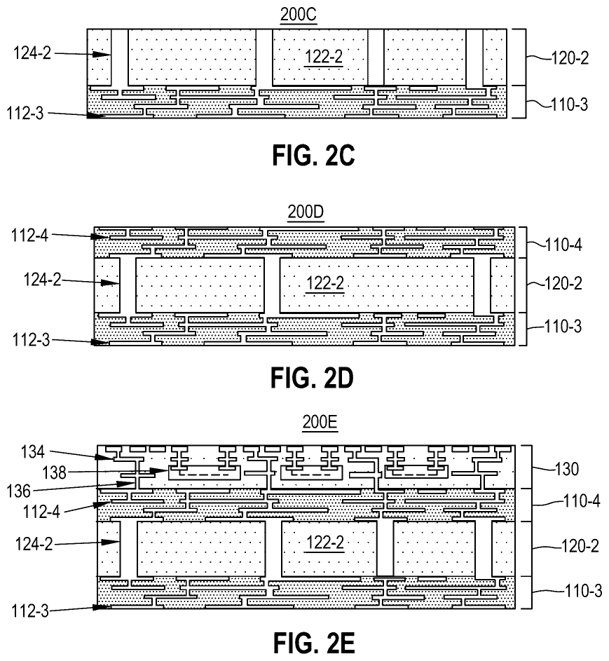

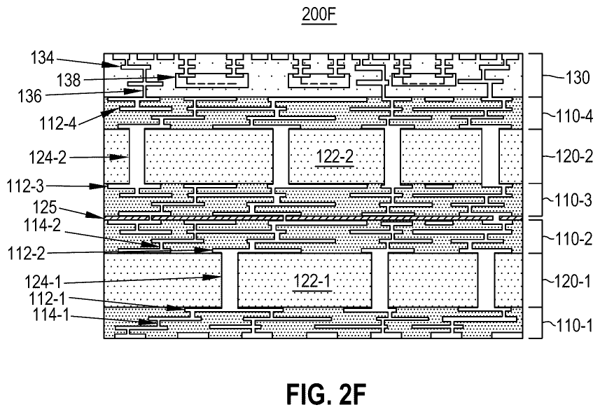

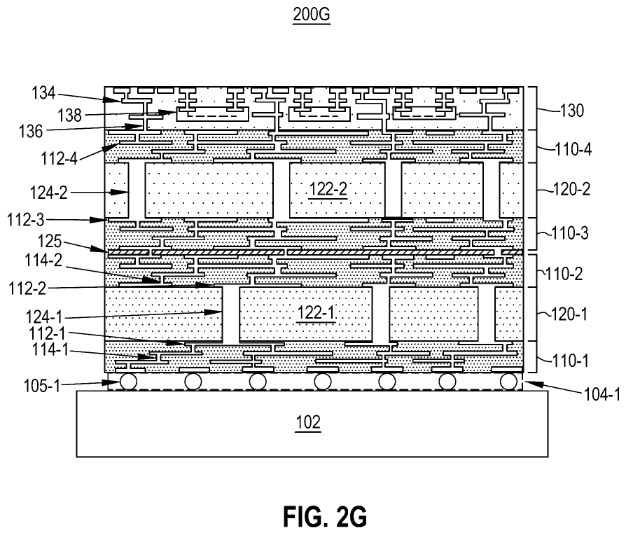

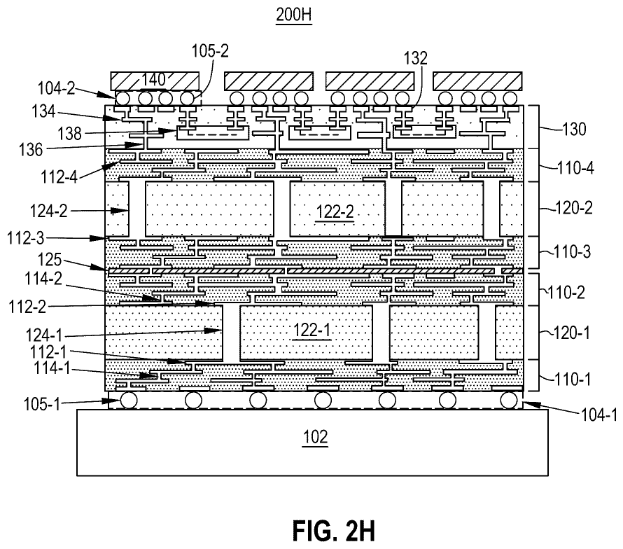

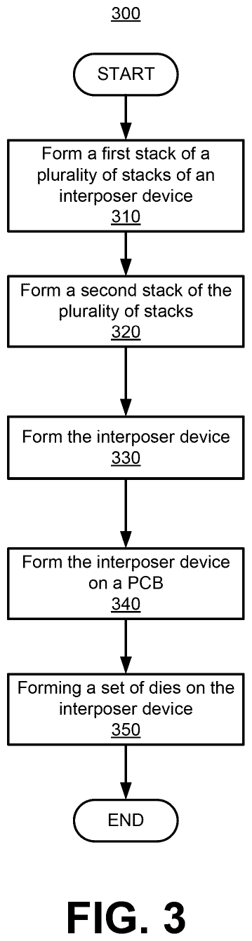

The first stack and the second stack can be manufactured separately. The first and second stacks can then be combined together using various manufacturing processes to form the interposer device. To complete fabrication of the system 100, the interposer device (e.g., the RDL 110-1) can be formed on the set of balls 104-1 formed on the PCB 102, the sets of balls including set of balls 104-2 can be formed on the hybrid interposer device (e.g., the RDL 110-4), and each die of the set of dies can be formed on its respective set of balls (e.g., die 140 formed on the set of balls 104-2). Further details regarding the fabrication of the system 100 will now be described below with reference to FIGS. 2A-3.

FIGS. 2A-2H are block diagrams illustrating an example process of forming the system 100, in accordance with some embodiments. For example, FIG. 2A is a diagram 200A showing the formation of the core 120-1, and the formation of the RDL 110-1 on the core 120-1. Forming the core 120-1 can include forming the core substrate 122-1, and forming the first set of TSVs including TSV 124-1 within the core substrate 122-1. For example, forming the first set of TSVs within the core substrate 122-1 can include forming (e.g., drilling) a first set of holes from a first end of the core substrate 122-1 to a second end of the core substrate 122-1, and filling each hole of the set of holes with conductive material to form the first set of TSVs. FIG. 2B is a diagram 200C showing the formation of the RDL 110-2 on the core 120-1. FIGS. 2A-2B collective describe the formation of a first stack of a plurality of stacks of the system 100.

FIG. 2C is a diagram 200C showing the formation of the core 120-2, and the formation of the RDL 110-3 on the core 120-2. Forming the core 120-2 can include the core substrate 122-2. and forming the second set of TSVs including TSV 124-2 within the core substrate 122-2. For example, forming the second set of TSVs within the core substrate 122-2 can include forming (e.g., drilling) a second set of holes from a first end of the core substrate 122-2 to a second end of the core substrate 122-2, and filling each hole of the set of holes with conductive material to form the second set of TSVs. FIG. 2D is a diagram 200F showing the formation of the RDL 110-4 on the core 120-2.

FIG. 2E is a diagram 200E showing the formation of the interposer 130 on the RDL 110-4. Forming the interposer 130 can include forming the interposer substrate 132 on the RDL 110-4, and forming, within the interposer substrate 132, a set of interconnect structures. The set of interconnect structures can include conductive lines (e.g., conductive line 134), vias (e.g., via 136), and a set of bridges (e.g., bridge 138). FIGS. 2C-2E collective describe the formation of a second stack (e.g., final stack) of a plurality of stacks of the system 100.

FIG. 2F is a diagram 200F showing the formation of an interposer device (e.g., hybrid interposer device”) including the first stack and the second stack. More specifically, in this example, the interposer device is formed from two stacks, in which the first stack is an initial stack of the interposer device and the second stack is a final stack of the interposer device. Forming the interposer device can include hybrid bonding the first stack to the second stack. In some embodiments, the interface 125 is formed between the first stack and the second stack. In some embodiments, the interposer device includes at least one additional stack including a third core formed between the first stack and the second stack.

FIG. 2G is a diagram 200G showing the formation of the interposer device on the set of balls 104-1 formed on the PCB 102. More specifically, the set of balls 104-1 is formed on the RDL 110-1, corresponding to a first side of the interposer device.

FIG. 2H is a diagram 200H showing the formation of multiple sets of balls including the set of balls 104-2 on the interposer device. More specifically, the multiple sets of balls are formed on the RDL 110-4, corresponding to a second side of the interposer device opposite the first side of the interposer device. The diagram 200K further shows the formation of a set of dies including the die 140 on the multiple sets of balls. More specifically, each die of the set of dies is formed on a respective set of balls of the multiple sets of balls formed. For example, the die 140 is formed on the set of balls 104-2. Further details regarding FIGS. 2A-2H are described above with reference to FIG. 1 and will now be described below with reference to FIG. 3.

FIG. 3 is a block diagram of an example method of forming a system or device including an interposer device with multiple interposer cores (e.g., a hybrid interposer device), in accordance with some embodiments.

At block 310, a first stack of a plurality of stacks an interposer device is formed. In some embodiments, the first stack is an initial stack of the plurality of stacks of the interposer device. For example, the first stack can include a first core located between a first RDL and a second RDL (e.g., the core 120-1 located between the RDL 110-1 and the RDL 110-2 of FIG. 1). The first core can include a first core substrate formed from a first material, and a first set of TSVs formed from a first end of the first core substrate to a second end of the first core substrate opposite the first end. Each TSV of the first set of TSVs can be in contact with a conductive line of the first RDL and a conductive line of the second RDL. The first material can be any suitable material. Examples of suitable materials include Si, glass, an organic material, a laminate material, etc.

In some embodiments, forming the first stack includes forming the first core by forming the first set of TSVs within the first core substrate, forming the first RDL on a first side of the first core, and forming the second RDL on a second side of the first core opposite the first side. For example, forming the first set of TSVs within the first core substrate can include forming (e.g., drilling) a first set of holes from the first end of the first core substrate to the second end of the first core substrate, and filling each hole of the set of holes with conductive material.

At block 320, a second stack of the plurality of stacks is formed. In some

embodiments, the second stack is a final stack of the plurality of stacks of the interposer device. For example, the second stack can include a second core located between a third RDL and a fourth RDL (e.g., the core 120-2 located between the RDL 110-3 and the RDL 110-4 of FIG. 1). The second core can include a second core substrate formed from a second material, and a second set of TSVs formed from a first end of the second core substrate to a second end of the second core substrate opposite the first end. Each TSV of the second set of TSVs can be in contact with a conductive line of the third RDL and a conductive line of the fourth RDL. The second material can be any suitable material. Examples of suitable materials include Si, glass, an organic material, a laminate material, etc. In some embodiments, the second material is different from the first material. In some embodiments, the second material is the same as the first material.

In some embodiments, forming the second stack includes forming the second core by forming the second set of TSVs within the second core substrate, forming the third RDL on a first side of the second core, and forming the fourth RDL on a second side of the second core opposite of the first side. For example, forming the second set of TSVs within the second core substrate can include forming (e.g., drilling) a second set of holes from the first end of the second core substrate to the second end of the second core substrate, and filling each hole of the second set of holes with conductive material.

The second stack can further include an interposer. In some embodiments, the interposer is formed after forming a sub-stack including the second core, the third RDL and the fourth RDL. In some embodiments, the interposer is formed during the fabrication of the sub-stack. The interposer can include an interposer substrate formed from a third material, and a set of interconnect structures formed within the interposer substrate. For example, the set of interconnect structures of the interposer can include conductive lines, vias and a set of bridges (e.g., a set of EMIBs). The third material can be any suitable material. In some embodiments, the third material is an organic material. In some embodiments, the third material is different from at least one of the first material. In some embodiments, the third material is different from both the first material and the second material. In some embodiments, the third material is the same as the first material and the second material.

At block 330, the interposer device is formed. For example, forming the interposer device can include combining each stack of the plurality of stacks. In some embodiments, the plurality of stacks further includes at least a third stack. In some embodiments, forming the interposer device includes combining each stack of the plurality of stacks using hybrid bonding. In some embodiments, forming the interposer device includes forming at least one solder resist between adjacent stacks of the plurality of stacks (e.g., the interface 125 of FIG. 1).

At block 340, the interposer device is formed on a PCB (e.g., the PCB 102 of FIG. 1). More specifically, the PCB can be formed with respect to a first side of the hybrid interposer device. In some embodiments, forming the interposer device on the PCB includes forming a set of balls (e.g., the set balls 104-1 of FIG. 1) on the PCB, and forming the interposer device on the set of balls. For example, each ball of the set of balls formed on the PCB can be in contact with a conductive line of the first RDL of the first stack.

At block 350, a set of dies (e.g., the set of dies including die 140 of FIG. 1) is formed on the interposer device. More specifically, the sets of dies can be formed on a second side of the interposer device opposite the first side. In particular, the set of dies can be formed on the interposer, which can be formed on or included in the final stack of the plurality of stacks (e.g., the second stack). In some embodiments, forming the set of dies on the interposer device includes forming multiple sets of balls (multiple BGAs) on the interposer. For example, each ball of a set of balls formed on the interposer can be in contact with a conductive line of the interposer. Adjacent dies of the set of dies can be electrically connected using respective bridges of the set of bridges of the interposer.

Blocks 310-350 can be performed in any suitable order. In some embodiments, the first stack is formed before the second stack. In some embodiments, the first stack is formed after the second stack. In some embodiments, the first stack is formed concurrently with the second stack. In some embodiments, the interposer device is formed on the PCB before the set of dies is formed on the interposer device. In some embodiments, the interposer device is formed on the PCB after the set of dies is formed on the interposer device. Further details regarding blocks 310-350 are described above with reference to FIGS. 1-2H.

The preceding description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other implementation examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

What is claimed is:

1. A system comprising:
a first stack of an interposer device, wherein the first stack comprises a first core comprising a first core substrate; and
a second stack of the interposer device, wherein the second stack comprises a second core comprising a second core substrate.

2. The system of claim 1, wherein the first core substrate comprises a same material as the second core substrate.

3. The system of claim 1, wherein the first core substrate comprises a different material from the second core substrate.

4. The system of claim 1, wherein at least one of the first core substrate or the second core substrate comprises silicon.

5. The system of claim 1, wherein at least one of the first core substrate or the second core substrate comprises glass.

6. The system of claim 1, wherein at least one of the first core substrate or the second core substrate comprises a laminate material.

7. The system of claim 1, wherein at least one of the first core substrate or the second core substrate comprises an organic material.

8. The system of claim 1, wherein the second stack further comprises an interposer formed on the second core, wherein the interposer comprises an interposer substrate.

9. The system of claim 8, wherein the interposer substrate comprises an organic material.

10. The system of claim 8, wherein the interposer further comprises a set of bridges.

11. The system of claim 1, wherein:
the first stack further comprises a first redistribution layer (RDL) and a second RDL;
the first core is located between the first RDL and the second RDL;
the second stack further comprises a third RDL and a fourth RDL; and
the second core is located between the third RDL and the fourth RDL.

12. The system of claim 11, wherein:
the first core comprises a first set of through substrate vias (TSVs) formed within the first core substrate;
each TSV of the first set of TSVs is in contact with a first conductive line of the first RDL and a second conductive line of the second RDL;
the second core comprises a second set of TSVs formed within the second core substrate; and
each TSV of the second set of TSVs is in contact with a third conductive line of the third RDL and a fourth conductive line of the fourth RDL.

13. The system of claim 1, further comprising:
a printed circuit board; and
a set of balls formed on the printed circuit board, wherein the first stack is formed on the set of balls;
a plurality of sets of balls formed on the second stack; and
a plurality of dies, wherein each die of the plurality of dies is formed on a respective set of balls of the plurality of sets of balls formed on the second stack.

14. A method comprising:
forming a first stack of a plurality of stacks of an interposer device, wherein the first stack comprises a first core comprising a first core substrate;
forming a second stack of the plurality of stacks, wherein the second stack comprises a second core comprising a second core substrate; and
forming the interposer device by combining each stack of the plurality of stacks.

15. The method of claim 14, wherein forming the second stack further comprises forming an interposer on the second core.

16. The method of claim 15, wherein the interposer comprises an organic material.

17. The method of claim 14, wherein:
forming the first stack further comprises forming a first redistribution layer (RDL) on a first side of the first core and a second RDL on a second side of the first core opposite the first side of the first core; and
forming the second stack further comprises forming a third RDL on a first side of the second core and forming a fourth RDL on a second side of the second core opposite the first side of the second core.

18. The method of claim 17, wherein:
forming the first stack further comprises forming a first set of through substrate vias (TSVs) within the first core substrate;
each TSV of the first set of TSVs is in contact with a first conductive line of and a second conductive line of the second RDL;
forming the second stack further comprises forming a second set of TSVs within the second core substrate; and
each TSV of the second set of TSVs is in contact with a third conductive line of the third RDL and a fourth conductive line of the fourth RDL.

19. The method of claim 14, further comprising forming the first stack on a set of balls formed on a printed circuit board (PCB).

20. The method of claim 14, further comprising:
forming a plurality of sets of balls on the second stack; and
forming, on each set of balls of the plurality of sets of balls, a respective die of a plurality of dies.
